(19) United States
(12) Patent Application Publication
(10) Pub. No.: US 2019/0214323 A1
(43) Pub. Date: Jul. 11, 2019

(54) FILLER COMPOSITIONS AND UNDERFILL COMPOSITIONS AND MOLDING COMPOUNDS INCLUDING THE SAME FOR PREPARING SEMICONDUCTOR PACKAGES

(71) Applicant: Advanced Semiconductor Engineering, Inc., Kaohsiung (TW)

(72) Inventors: Ya-Yu HSIEH, Kaohsiung (TW); Hong-Ping LIN, Kaohsiung (TW); Dao-Long CHEN, Kaohsiung (TW); Ping-Feng YANG, Kaohsiung (TW); Meng-Kai SHIH, Kaohsiung (TW)

(73) Assignee: Advanced Semiconductor Engineering, Inc., Kaohsiung (TW)

(21) Appl. No.: 16/354,049

(22) Filed: Mar. 14, 2019

Related U.S. Application Data
(63) Continuation of application No. 14/943,519, filed on Nov. 17, 2015.

(51) Int. Cl. H01L 23/29; C08G 59/42; C08K 5/5435; C08K 5/544; C08K 3/04; C08K 3/36; H01L 23/00; C09D 163/00

(52) U.S. Cl. CPC H01L 23/295; H01L 21/563; C08K 5/5435; C08K 5/544; C08K 3/04; C08K 3/36; H01L 23/296; H01L 24/29; C09D 163/00; H01L 2224/73265; H01L 2224/73204; H01L 2224/48247; H01L 2224/48091; H01L 2224/32245; H01L 2224/32225; H01L 2224/29393; H01L 2224/16227; H01L 24/48; H01L 24/32; H01L 24/16; H01L 2924/15311; H01L 2924/3511; H01L 2924/3512; H01L 2224/2929; H01L 2224/29387; H01L 2924/01006; C08G 59/42

(57) ABSTRACT

A semiconductor package includes a filler composition, wherein the filler composition includes particles each including both carbon and silica, wherein the filler composition is substantially devoid of alumina or silicon carbide, and the filler composition has a weight ratio of carbon to silica of at least greater than 1.0.

### CROSS-REFERENCE TO RELATED APPLICATIONS

This application is a continuation of U.S. patent application Ser. No. 14/943,519, filed Nov. 17, 2015, the contents of which are incorporated herein by reference in their entirety.

### BACKGROUND

### 1. Technical Field

The present disclosure relates to filler compositions, and underfill compositions and molding compounds including the same for preparing semiconductor packages, such as a flip-chip type semiconductor package or a wire-bond type semiconductor package.

### 2. Description of the Related Art

As the semiconductor industry continues its aggressive miniaturization of circuit feature size, low dielectric constant (low-K) materials have been developed to reduce capacitive effects in metallization layers of integrated circuits. Nevertheless, the low-K materials present new challenges in both manufacturing and packaging operations. The robustness and reliability of a semiconductor package may be compromised by differences in performance resulting from the use of low-K materials in semiconductor devices with respect to thermal coefficient of expansion, adhesion to adjacent layers, mechanical strength, thermal conductivity, and moisture absorption.

When layers of materials having different coefficients of thermal expansion are bonded together, the layers can expand and contract at different rates, resulting in strains in adjacent and neighboring layers. Therefore, semiconductor devices having low-K layers can be more prone to delamination because of an underfill composition, a molding compound, or other materials that are in close contact with the semiconductor devices. Moreover, since a mechanical strength of low-K layers is low in general due to its brittle nature, semiconductor devices containing low-K dielectrics can be prone to breaking or cracking during processes that involve physical contact with a semiconductor device surface, such as wire bonding and wafer probing, or processes that result in bending stresses such as molding and underfill curing, solder ball reflow, and temperature cycling.

Given the above, it would be therefore desirable to provide semiconductor packaging materials suitable for advanced applications, such as a filler composition useful for an underfill composition, a molding compound, an adhesive, or other materials that are in close contact with a semiconductor device, to reduce a die stress, to reduce inner layer delamination in a low-K material such as low-K silicon, or to reduce strains on a solder joint of a die.

### SUMMARY

One aspect of some embodiments of the present disclosure relates to a filler composition for a semiconductor package, where the filler composition includes carbon and silica.

Another aspect of some embodiments of the present disclosure relates to an underfill composition, a molding compound, and an adhesive for a semiconductor package. The underfill composition, the molding compound, and the adhesive include the filler composition mentioned above.

Another aspect of some embodiments of the present disclosure relates to a process for preparing a filler composition for a semiconductor package, including: (a) combining phytoliths and a solvent to form a dispersion; (b) modifying a pH value of the dispersion to form an acidic dispersion; (c) carrying out a heat treatment on the acidic dispersion; and (d) calcining at least a portion of the acidic dispersion in a reducing environment to form the filler composition.

Another aspect of some embodiments of the present disclosure relates to a semiconductor package including a filler composition, an underfill composition, a molding compound, or an adhesive mentioned above.

### BRIEF DESCRIPTION OF THE DRAWINGS

FIG. 1 illustrates a cross-sectional view of a flip-chip type semiconductor package according to an embodiment of the present disclosure.

FIG. 2 illustrates a cross-sectional view of a wire-bonding type semiconductor package according to an embodiment of the present disclosure.

### DETAILED DESCRIPTION

A filler composition according to some embodiments of the present disclosure includes carbon and silica. In some embodiments, carbon can be in an elemental form, although the presence of carbon-containing compounds is also encompassed for some embodiments. In some embodiments, silica can be represented as SiO2, and can be amorphous, crystalline, or a combination of amorphous and crystalline phases.

Carbon can be obtained from an organic material, an inorganic material, or a mixture thereof. The organic material may be obtained from natural resources, including, but not limited to, phytoliths, coal, peat, oil, methane clathrates, or a mixture thereof or from natural waste, such as vegetations. The inorganic material may include, but is not limited to, limestone, dolomite, carbon dioxide, or a mixture thereof.

Silica can be obtained from an organic material, an inorganic material, or a mixture thereof. The organic material may include, but is not limited to, phytoliths. In one or more embodiments, phytoliths can be obtained from husks, rice straws, or a mixture thereof. The husks may include, but is not limited to, rice husks, coconut shells, or a mixture thereof. The inorganic material may include, but is not limited to, sand, soil, or a mixture thereof.

In one or more embodiments, carbon and silica are obtained from the same source. For example, carbon and silica may be obtained from phytoliths, such as husks, rice straws, or a mixture thereof. In one or more embodiments, carbon and silica are obtained from rice husks, coconut shells, or a mixture thereof. By providing carbon from the same source used for providing silica, associated costs for providing carbon, such as the costs for providing the raw materials and the costs for processing the materials, can be reduced or eliminated.

In addition, by providing carbon and silica from a natural resource such as phytoliths or from a natural waste, the associated costs, such as the costs to exploit or provide raw materials for carbon and silica and the costs for processing the materials, can be reduced or eliminated. Moreover, since a filler composition can be produced as carbon and silica that are obtained from a natural resource such as phytoliths, the manufacturing of the filler composition can be environmental friendly as producing a lower carbon footprint, compared to conventional manufacturing processes of filler compositions.

Additionally, a filler composition of some embodiments can influence a coefficient of thermal expansion (CTE) and a Young's modulus of a composition to which the filler composition is added. It is found that by adding the filler composition to an underfill composition or an adhesive between a die and a semiconductor structure (such as a substrate, an interposer, or a package) to be mated with the die, or to a molding compound to encapsulate the die, a CTE and a Young's modulus of the underfill composition, the adhesive or the molding compound can be reduced, thereby reducing stress on the die and warpage of a resulting semiconductor package. In some embodiments, a CTE of the underfill composition, the adhesive or the molding compound below its glass transition temperature Tg can be about 54 ppm/° C. or less, about 50 ppm/° C. or less, about 45 ppm/° C. or less, about 40 ppm/° C. or less, about 35 ppm/° C. or less, or about 32 ppm/° C. or less, and a Young's modulus of the underfill composition, the adhesive or the molding compound below its glass transition temperature Tg can be about 6.5 GPa or less, about 6.1 GPa or less, about 5.5 GPa or less, about 5 GPa or less, about 4.5 GPa or less, about 4 GPa or less, about 3.8 GPa or less, or about 3.6 GPa or less. Moreover, according to some embodiments, the underfill composition, the adhesive or the molding compound can possess a higher thermal conductivity, such as a thermal conductivity of about 0.2 W/mK or greater, about 0.25 W/mK or greater, about 0.3 W/mK or greater, about 0.35 W/mK or greater, about 0.4 W/mK or greater, about 0.45 W/mK or greater, about 0.5 W/mK or greater, or about 0.55 W/mK or greater.

In some embodiments, a process for preparing a filler composition includes: (a) combining phytoliths and a solvent to form a dispersion; (b) modifying a pH value of the dispersion to form an acidic dispersion; (c) carrying out a heat treatment on the acidic dispersion; and (d) calcining at least a portion of the acidic dispersion in a reducing environment to form the filler composition.

In some embodiments, the phytoliths in (a) can be obtained from husks, rice straws, or a mixture thereof, and the solvent in (a) can be an inorganic solvent, such as water, or an organic solvent, such as a protic or aprotic polar, organic solvent. In some embodiments, the acidic dispersion in (b) can have a pH value less than about 7, such as about 6.5 or less, about 6 or less, about 5.5 or less, about 5 or less, about 4.5 or less, or about 4 or less. In some embodiments, the heat treatment in (c) can include applying a hydrothermal process at a temperature in a range of about 50° C. to about 200° C. or about 80° C. to about 150° C. for about 0.5 hour to about 4 hours or about 1 hour to about 3 hours. In some embodiments, the calcining in (d) can be applied at a temperature in a range of about 600° C. to about 1000° C. or about 700° C. to about 900° C., and the reducing environment can be a nitrogen environment or other environment substantially devoid of oxygen, such that an amount of oxygen is less than about 5% by weight or less than about 1% by weight.

In some embodiments, an amount of carbon in a filler composition is at least about 5% by weight of the filler composition, such as about 8% or more, about 10% or more, about 15% or more, about 20% or more, about 25% or more, or about 30% or more by weight of the composition. For example, the amount of carbon in the filler composition can be about 30% to about 85% by weight, about 40% to about 75% by weight, or about 48% to about 70% by weight of the composition.

In some embodiments, an amount of silica in a filler composition is at least about 5% by weight of the filler composition and up to about 95% by weight of the filler composition, such as up to about 92%, up to about 90%, up to about 85%, up to about 80%, up to about 75%, or up to about 70% by weight of the composition. For example, the amount of silica in the filler composition can be about 15% to about 70% by weight, about 25% to about 60% by weight, or about 30% to about 52% by weight of the composition.

In one or more embodiments, a ratio of amounts of carbon to silica (by weight) in a filler composition is from about 0.4 to about 5.7, such as from about 0.6 to about 3.0, or from about 0.9 to about 2.3. In one or more embodiments, a ratio of amounts of carbon to silica (by weight) in a filler composition is at least about 0.05, such as about 0.1 or more, about 0.15 or more, about 0.2 or more, about 0.25 or more, about 0.3 or more, about 0.35 or more, or about 0.4 or more, and can be up to or less than about 1, or can be greater than about 1, such as up to about 2.3 or more, up to about 3 or more, or up to about 5.7 or more.

In one or more embodiments, a filler composition can be substantially devoid of alumina, such that an amount of alumina in the filler composition is less than about 5% by weight of the filler composition, such as less than about 1% by weight of the composition. In one or more embodiments, a filler composition can be substantially devoid of silicon carbide (SiC), such that an amount of SiC in the filler composition is less than about 5% by weight of the filler composition, such as less than about 1% by weight of the composition.

In one or more embodiments, a filler composition can be composed of, or can consist essentially of, particles with sizes (e.g., diameters) of about 50 μm or less, about 40 μm or less, about 30 μm or less, about 1 μm or less, or about 0.1 μm or less, or with sizes from about 0.1 μm to about 50 from about 0.2 μm to about 40 or from about 0.5 μm to about 30 In one or more embodiments, a median size (by volume or weight) of particles in a filler composition can be about 50 μm or less, about 40 μm or less, about 30 μm or less, about 1 μm or less, or about 0.1 μm or less, or can be in a range from about 0.1 μm to about 50 from about 0.2 μm to about 40 or from about 0.5 μm to about 30 In one or more embodiments, particles in a filler composition can be composed of both carbon and silica, and, in one or more other embodiments, the filler composition can include a first population of particles composed primarily of carbon, and a second population of particles composed primarily of silica.

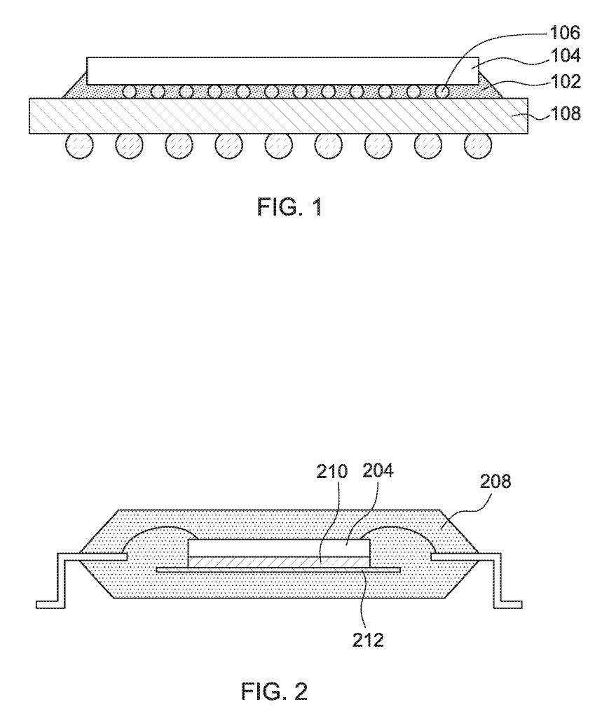

Referring to an embodiment of a semiconductor package in FIG. 1, an underfill composition 102 is introduced to fill a gap between a die 104, solder bumps 106, and a semiconductor structure 108 to mitigate against cracking or dislocation of the solder bumps 106 caused by interfacial die and semiconductor structure stress and solder bump strain in the package. In one or more embodiments, the underfill composition 102 includes a base material and a filler composition according to embodiments of the present disclosure.

The base material may include an epoxy component. In one or more embodiments, the epoxy component may include one or more bisphenol-based epoxies. These bisphenol-based epoxies may be selected from bisphenol A epoxies, bisphenol F epoxies, bisphenol S epoxies, and a combination thereof. In one or more embodiments, these bisphenol-based epoxies may be silane-modified epoxies. In addition to, or in place of, these bisphenol-based epoxies, other epoxy compounds may be included as the epoxy component. For instance, cycloaliphatic epoxies, such as 3,4-epoxycyclohexylmethyl-3,4-epoxycyclohexylcarbonate, can be used. In addition, if desired, monofunctional, difunctional or multifunctional reactive diluents to either, or both, adjust a viscosity and lower a Tg can be included, such as an ether selected from butyl glycidyl ether, cresyl glycidyl ether, polyethylene glycol glycidyl ether, polypropylene glycol glycidyl ether, or a combination thereof.

The underfill composition 102 may include a hardener, for example, as part of the base material. A cyanate ester, an aromatic amine, or an anhydride may be used. In one or more embodiments, the hardener is an anhydride.

The underfill composition 102 may include a catalyst, for example, as part of the base material. Many different materials can be used as the catalyst depending upon the temperature at which curing is desired to occur. For example, to achieve curing at a temperature of about 120° C. to about 175° C., the catalyst can be an amine.

In one or more embodiments, the underfill composition 102 may further include a silane coupling agent to improve the compatibility between the epoxy component and the filler composition. The silane coupling agent may be, but not limited to, 3-aminopropyltriethoxysilane (APTES), 3-glycidoxypropyltriethoxysilane (GPTES), or a combination thereof. In place of, or in combination with, the silane coupling agent, the filler composition can be treated by applying electromagnetic irradiation, such as microwave irradiation at a power level of about 300 W to about 1200 W or about 500 W to about 900 W one or more times for a duration of about 30 seconds to about 150 seconds per treatment duration.

In one or more embodiments, the underfill composition 102 may include from about 20% to about 80% by weight of the filler composition, from about 30% to about 70% by weight of the filler composition, or from about 45% to about 65% by weight of the filler composition.

In one or more embodiments, an amount of the epoxy component in the underfill composition 102 can be from about 20% to about 80% by weight, from about 30% to about 70% by weight, from about 25% to about 50% by weight, or from about 35% to about 55% by weight of the underfill composition 102.

In one or more embodiments, an amount of the hardener in the base material can be from about 3% to about 9%, from about 13% to about 31%, or from about 16% to about 24% by weight of the epoxy component. In one or more embodiments, an amount of the hardener in the underfill composition 102 can be from about 10% to about 40% by weight, from about 15% to about 35% by weight, or from about 20% to about 30% by weight of the underfill composition 102.

In one or more embodiments, an amount of the catalyst in the base material can be from about 0.05% to about 1% by weight of the underfill composition 102.

In one or more embodiments, the silane coupling agent may be present in the underfill composition 102 in an amount from about 1% to about 5% by weight of the underfill composition 102.

Referring to an embodiment of a semiconductor package in FIG. 2, a molding compound is used to cover or encapsulate a die 204 to form an encapsulant 208 to protect the die 204 from unfavorable influences of an exterior environment. In one or more embodiments, the molding compound includes a base material and a filler composition according to embodiments of the present disclosure.

The base material and the filler composition used in the molding compound can be similar to those described in connection with the underfill composition 102 of FIG. 1. In one or more embodiments, the molding compound may include from about 60% to about 95% by weight of the filler composition, from about 65% to about 90% by weight of the filler composition, or from about 70% to about 85% by weight of the filler composition. An amount of an epoxy component in the molding compound can be from about 5% to about 40% by weight, from about 10% to about 35% by weight, or from about 15% to about 30% by weight of the molding compound.

In one or more embodiments, a filler composition according to embodiments of the present disclosure can also be included in an adhesive 210 illustrated in FIG. 2 for disposing the die 204 on a pad 212. The filler composition and a base material used in the adhesive 210 may be similar to those used in the underfill composition 102 of FIG. 1 or the molding compound of FIG. 2. The adhesive 210 may include from about 20% to about 80% by weight of the filler composition, from about 30% to about 70% by weight of the filler composition, or from about 45% to about 65% by weight of the filler composition.

### EXAMPLES

The following examples describe specific aspects of some embodiments of this disclosure to illustrate and provide a description for those of ordinary skill in the art. The examples should not be construed as limiting this disclosure, as the examples merely provide specific methodology useful in understanding and practicing some embodiments of this disclosure.

### Example 1

A filler composition was prepared by first dispersing phytoliths (Taiwanese rice husks) in a solvent (water). The pH value of the rice husks solution was modified to become acidic. The solution was then heated at about 100° C. by a hydrothermal process in an oven for about 2 hours. After this, the solution was washed with de-ionized water and then dried at about 100° C. The solution was then calcined at about 800° C. under nitrogen or an environment substantially devoid of oxygen, and a filler composition can be obtained. The filler composition can be further ground by a ball grinder or a planetary ball miller to form particles with diameters of less than about 1 μm or less than about 0.1 μm or diameters from about 0.1 μm to about 50 The resulting filler composition has a (weight) ratio of carbon to silica of about 1.5 to about 2.0.

### Example 2

A filler composition was prepared by a procedure similar to that described in Example 1 except that Japanese rice husks, rather than Taiwanese rice husks, were used. The resulting filler composition has a (weight) ratio of carbon to silica of about 0.9 to 1.0.

### Example 3

An underfill composition was prepared according to the following procedure. An epoxy component (such as bisphenol A) was heated. Then, the filler composition according to Example 1 or 2 was added to the heated epoxy component in an amount of about 17% by weight of the composition, which was then mixed at about 95° C. for about 8 hours. After this, a hardener (an anhydride) was added to the mixture, which was mixed at about 60° C. A (weight) ratio of the epoxy component to the anhydride is about 1:0.8. Then, a suitable amount of catalyst was added to the mixture, which was mixed at about 60° C. After the mixing, an underfill composition can be obtained.

### Example 4

The procedure in this example for preparing an underfill composition is similar to that described in Example 3 except that the filler composition according to Example 1 or 2 was added to the heated epoxy component in an amount of about 20% by weight of the composition.

### Example 5

The procedure in this example for preparing an underfill composition is similar to that described in Example 3 except that the filler composition according to Example 1 or 2 was added to the heated epoxy component in an amount of about 29% by weight of the composition.

### Example 6

The procedure in this example for preparing an underfill composition is similar to that described in Example 3 except that the filler composition according to Example 1 or 2 was added to the heated epoxy component in an amount of about 31% by weight of the composition.

### Example 7

The procedure in this example for preparing an underfill composition is similar to that described in Example 3 except that the filler composition according to Example 1 or 2 was added to the heated epoxy component in an amount of about 39% by weight of the composition.

### Example 8

The procedure in this example for preparing an underfill composition is similar to that described in Example 3 except that the filler composition according to Example 1 or 2 was added to the heated epoxy component in an amount of about 43% by weight of the composition.

### Example 9

The procedure in this example for preparing an underfill composition is similar to that described in Example 3 except that the filler composition according to Example 1 or 2 was added to the heated epoxy component in an amount of about 46% by weight of the composition.

### Example 10

The procedure in this example for preparing an underfill composition is similar to that described in Example 7 except that the filler composition of Example 1 was microwaved once at about 700 W for about 90 seconds.

### Example 11

The procedure in this example for preparing an underfill composition is similar to that described in Example 7 except that the filler composition of Example 1 was microwaved twice at about 700 W for about 90 seconds.

### Example 12

The procedure in this example for preparing an underfill composition is similar to that described in Example 7 except that the filler composition of Example 1 was microwaved three times at about 700 W for about 90 seconds.

### Example 13

The procedure in this example for preparing an underfill composition is similar to that described in Example 7 except that the filler composition of Example 1 was microwaved four times at about 700 W for about 90 seconds.

### Example 14

The procedure in this example for preparing an underfill composition is similar to that described in Example 7 except that a silane coupling agent (3-aminopropyltriethoxysilane (APTES)) was added to the underfill composition.

### Example 15

The procedure in this example for preparing an underfill composition is similar to that described in Example 7 except that a silane coupling agent (3-glycidoxypropyltriethoxysilane (GPTES)) was added to the underfill composition.

Details of the components of the underfill compositions of Examples 3 to 15 are set forth below in Tables 1 and 2.

TABLE 1

| Constituents | | Example Nos./Amount (wt. %) | | | | | |
|---|---|---|---|---|---|---|---|
| Type | Identity | 3 | 4 | 5 | 6 | 7 | 8 |
| Epoxy | Bisphenol | 46 | 44 | 40 | 38 | 34 | 32 |
| | A epoxy | | | | | | |
| Hardener | Anhydride | 36.6 | 35.6 | 30.7 | 30.7 | 26.7 | 24.7 |
| Catalyst | Amine | 0.4 | 0.4 | 0.3 | 0.3 | 0.3 | 0.3 |
| Filler | Carbon/silica | 17 | 20 | 29 | 31 | 39 | 43 |
| composition | | | | | | | |
| (wt. %) | | | | | | | |
| Treatment | Microwave | NA | NA | NA | NA | NA | NA |
| | Silane coupling | NA | NA | NA | NA | NA | NA |
| | agent | | | | | | |

TABLE 2

| Constituents | | Example Nos./Amount (wt. %) | | | | | | |
|---|---|---|---|---|---|---|---|---|
| Type | Identity | 9 | 10 | 11 | 12 | 13 | 14 | 15 |
| Epoxy | Bisphenol A epoxy | 30 | 34 | 34 | 34 | 34 | 34 | 34 |
| Hardener | Anhydride | 23.8 | 26.7 | 26.7 | 26.7 | 26.7 | 26.7 | 26.7 |
| Catalyst | Amine | 0.2 | 0.3 | 0.3 | 0.3 | 0.3 | 0.3 | 0.3 |
| Filler composition | Carbon/silica | 46 | 39 | 39 | 39 | 39 | 39 | 39 |
| (wt. %) | | | | | | | | |
| Treatment | Microwave | NA | 1 time | 2 times | 3 times | 4 times | NA | NA |
| | Silane coupling | NA | NA | NA | NA | NA | APTES | GPTES |
| | agent | | | | | | | |

Physical properties of the underfill compositions of Examples 3 to 15 are set forth below in Tables 3 and 4. In the below, TMA denotes thermomechanical analysis.

TABLE 3

| | | Example Nos./Amount (wt. %) | | | | | |
|---|---|---|---|---|---|---|---|
| | | 3 | 4 | 5 | 6 | 7 | 8 |
| Filler composition | Carbon/silica | 17 | 20 | 29 | 31 | 39 | 43 |
| Treatment | Microwave | NA | NA | NA | NA | NA | NA |
| | Silane coupling agent | NA | NA | NA | NA | NA | NA |

| | | | | | | |
|---|---|---|---|---|---|---|
| Viscosity (cP) at room temperature | NA | NA | NA | NA | NA | NA |
| Tg (° C.) by TMA | 116.22 | 139.99 | 123 | 140.66 | 143.44 | 145.87 |
| CTE 1 (ppm/° C.) below Tg | 53.05 | 48.21 | 41.67 | 41.71 | 38.44 | 34.07 |
| CTE 2 (ppm/° C.) above Tg | 183.8 | 178.6 | 153.6 | 134.2 | 112.9 | 97.43 |
| Young's modulus (GPa) below Tg | 3.63 | 3.80 | 3.75 | 4.48 | 5.74 | 6.01 |
| Young's modulus (GPa) above Tg | NA | 0.23 | NA | 0.52 | 0.38 | 0.47 |
| Thermal conductivity (W/mK) | 0.25 | 0.22 | 0.29 | 0.34 | 0.41 | 0.44 |

TABLE 4

| | | Example Nos./Amount (wt. %) | | | | | | |
|---|---|---|---|---|---|---|---|---|
| | | 9 | 10 | 11 | 12 | 13 | 14 | 15 |
| Filler composition | Carbon/silica | 46 | 39 | 39 | 39 | 39 | 39 | 39 |
| Treatment | Microwave | NA | 1 time | 2 times | 3 times | 4 times | NA | NA |
| | Silane coupling agent | NA | NA | NA | NA | NA | APTES | GPTES |

| | | | | | | | |
|---|---|---|---|---|---|---|---|
| Viscosity (cP) at room temperature | NA | NA | NA | NA | NA | 40446 | 28044 |
| Tg (° C.) by TMA | 151.46 | 128.68 | 136.68 | 136.03 | 129.73 | 136.8 | 127.76 |
| CTE 1 (ppm/° C.) below Tg | 32.17 | 36.36 | 36.18 | 36.54 | 36.34 | 41.14 | 38.86 |
| CTE 2 (ppm/° C.) above Tg | 95.2 | 113.4 | 114.2 | 110.3 | 119.2 | 125.9 | 133.5 |
| Young's modulus (GPa) below Tg | 6.07 | 5.73 | 6.06 | 5.79 | 5.82 | 4.95 | 4.94 |
| Young's modulus (GPa) above Tg | 0.21 | 0.04 | 0.09 | 0.39 | 0.13 | 0.57 | 0.35 |
| Thermal conductivity (W/mK) | 0.47 | 0.45 | 0.46 | 0.51 | 0.52 | 0.55 | 0.52 |

Details of the components of underfill compositions of Comparative Examples 1 to 7 and their physical properties are set forth below in Table 5.

TABLE 5

| | Example Nos./Amount (wt. %) | | | | | | |
|---|---|---|---|---|---|---|---|
| | | | | C4 | C5 | | C7 |
| | C1 | C2 | C3 | (CBL- | (XS8449- | C6 | (Wong et |
| | (UA03) | (UA26) | (UA05) | C-3750) | 23) | (LSI) | al.) |
| Filler composition | silica | silica | silica | silica | alumina | alumina | SiC |
| Filler content (wt. %) | 55 | 65 | 55 | 65 | 65 | 20-30 | 40 |
| Viscosity (cP) at room temperature | 64898 | 57607 | 15000 | 18000 | 33000 | NA | NA |
| Tg (° C.) by TMA | 61.55 | 100 | 106.79 | 120 | 118 | 150 | 148.8 |
| CTE 1 (ppm/° C.) below Tg | 33.38 | 26 | 26.84 | 30 | 30 | 55-60 | 56.8 |
| CTE 2 (ppm/° C.) above Tg | 129 | 90 | 111 | 106 | 116 | NA | NA |
| Young's modulus (MPa) below Tg | 7764 | 11000 | 10261 | 8436 | 9200 | 3000-4000 | 3700 |
| Young's modulus (MPa) above Tg | 89.29 | 200 | 140.2 | 177 | NA | NA | NA |
| Thermal conductivity (W/mK) | 0.4 | 0.5 | 0.45 | 0.5 | 0.6 | NA | 0.29 |

Warpage evaluation results for Comparative Examples 1 and 2 and Examples 14 and 15 are set forth below in Table 6.

TABLE 6

| | | C1 | C2 | | |
|---|---|---|---|---|---|
| | | (UA03) | (UA26) | 14 | 15 |
| | | Filler composition | | | |
| | | | | Carbon/ | Carbon/ |
| | | silica | silica | silica | silica |
| Treatment | | GPTES | Unknown | APTES | GPTES |
| FCCSP* | Warpage Evaluation | −2.44 | −2.42 | −2.42 | −2.42 |
| (4 × 4) | Results at | | | | |
| | 25° C. (μm) | | | | |
| | Warpage Evaluation | 11.48 | 10.30 | 8.23 | 8.75 |
| | Results at | | | | |
| | 260° C. (μm) | | | | |
| FCCSP | Warpage Evaluation | −3.20 | −3.05 | −3.05 | −3.05 |
| (25 × 25) | Results at | | | | |
| | 25° C. (μm) | | | | |
| | Warpage Evaluation | 117.21 | 115.6 | 108.61 | 110.50 |
| | Results at | | | | |
| | 260° C. (μm) | | | | |
| FCBGA** | Warpage Evaluation | 130.32 | 141.68 | 141.06 | 139.99 |
| (25 × 25) | Results at | | | | |
| | 25° C. (μm) | | | | |
| | Warpage Evaluation | 1.25 | 1.31 | 1.31 | 1.31 |
| | Results at | | | | |
| | 260° C. (μm) | | | | |
| FCBGA | Warpage Evaluation | 426.89 | 382.52 | 384.77 | 388.23 |
| (45 × 45) | Results at | | | | |
| | 25° C. (μm) | | | | |
| | Warpage Evaluation | 0.74 | 0.78 | 0.78 | 0.78 |
| | Results at | | | | |
| | 260° C. (μm) | | | | |

*Flip-chip type chip scale package
**Flip-chip type ball grid array package

Extra low-K stress (ELK) evaluation results for Comparative Examples 1 and 3 and Example 14 are set forth below in Table 7.

TABLE 7

| | C1 | C3 | |
|---|---|---|---|
| | (UA03) | (UA05) | 14 |
| | Filler composition | | |
| | | | Carbon/ |
| | silica | silica | silica |
| Treatment | GPTES | Unknown | APTES |
| ELK Stress Evaluation at 25° C. | 175 | 170 | 163 |

According to the physical properties shown in Tables 3 and 4, it can be observed that an underfill composition including a filler composition according to the examples of the present disclosure can have a Young's modulus of less than about 6.1 GPa below Tg, and can be down to about 3.63 GPa (Example 3). In addition, an underfill composition including a filler composition according to the examples of the present disclosure can have a thermal conductivity of at least of about 0.22 W/mK (Example 4), and can be up to about 0.55 W/mK (Example 14). Moreover, it is noted that an underfill composition including a filler composition according to the examples of the present disclosure can achieve the advantageous properties mentioned above, while the CTE 1 values remain in a range from about 32.17 ppm/° C. to about 53.05 ppm/° C.

The physical properties shown in Table 5 for Comparative Examples 1 to 7 are compared against the physical properties shown in Tables 3 and 4 for Examples 3 to 15. According to the comparison, it can be observed that an underfill composition including an environmental friendly and cost effective filler composition according to the examples of the present disclosure would not compromise its Young's modulus below Tg and CTE 1 values. Quite to the contrary, some examples (such as Example 3) yielded a lower Young's modulus below Tg, while the CTE 1 values remain in a range from about 32.17 ppm/° C. to about 53.05 ppm/° C. Moreover, according to the comparison, some examples (such as Examples 12 to 15) can possess a higher thermal conductivity.

According to the warpage evaluation results shown in Table 6 for Comparative Examples 1 and 2 and Examples 14 and 15, it can be observed that an underfill composition replacing a conventional filler composition with an environmental friendly and cost effective filler composition according to the present disclosure would not compromise its warpage performance for a flip-chip type chip scale package (FCCSP) and a flip-chip type ball grid array package. Quite to the contrary, some examples (such as the examples for FCCSP) show an improvement in terms of reduce warpage.

According to the ELK evaluation results shown in Table 7 for Comparative Examples 1 and 3 and Example 14, it can be observed that an underfill composition replacing a conventional filler composition with an environmental friendly and cost effective filler composition according to the present disclosure would not compromise the low-K stress performance, but actually can improve the performance.

As used herein and not otherwise defined, the term “about” is used to describe and account for small variations. When used in conjunction with a value, the term can refer to instances in which the value occurs precisely as well as instances in which the value occurs to a close approximation. For example, when used in conjunction with a value, the term can refer to a range of variation of less than or equal to ±10% of that value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. As another example, two values, such as characterizing an amount, can be about the same or matching if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the term “size” refers to a characteristic dimension of an object. Thus, for example, a size of an object that is spherical can refer to a diameter of the object. In the case of an object that is non-spherical, a size of the object can refer to a diameter of a corresponding spherical object, where the corresponding spherical object exhibits or has a particular set of derivable or measurable characteristics that are substantially the same as those of the non-spherical object. Alternatively, or in conjunction, a size of a non-spherical object can refer to an average of various orthogonal dimensions of the object. When referring to a set of objects as having a particular size, it is contemplated that the objects can have a distribution of sizes around the particular size. Thus, as used herein, a size of a set of objects can refer to a typical size of a distribution of sizes, such as an average size, a median size, or a peak size.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, process, or process to the objective, spirit and scope of the present disclosure. All such modifications are intended to be within the scope of the claims appended hereto. While the processes disclosed herein have been described with reference to particular operations performed in a particular order, it will be understood that these operations may be combined, sub-divided, or re-ordered to form an equivalent process without departing from the teachings of the present disclosure. Accordingly, unless specifically indicated herein, the order and grouping of the operations are not limitations of the present disclosure.

What is claimed is:

1. A semiconductor package, comprising a filler composition, wherein the filler composition comprises particles each including both carbon and silica, wherein the filler composition is substantially devoid of alumina or silicon carbide, and the filler composition has a weight ratio of carbon to silica of at least greater than 1.0.

2. The semiconductor package according to claim 1, wherein an amount of carbon in the filler composition is at least 5% by weight of the filler composition.

3. The semiconductor package according to claim 1, wherein an amount of carbon in the filler composition is in a range of 30% to 85% by weight of the filler composition.

4. The semiconductor package according to claim 1, wherein an amount of silica in the filler composition is at least 5% by weight of the filler composition and less than 50% by weight of the filler composition.

5. The semiconductor package according to claim 1, wherein the particles having a median size, by weight, in a range of 0.1 μm to 50 μm.

6. The semiconductor package according to claim 1, wherein the carbon and silica are obtained from an organic material.

7. The semiconductor package according to claim 1, wherein the carbon and silica are obtained from phytoliths.

8. The semiconductor package according to claim 7, wherein the phytoliths are obtained from husks, rice straws, or mixtures thereof.

9. A semiconductor package, comprising:
an underfill composition comprising:
a base material; and
a filler composition, wherein the filler composition comprises particles each including both carbon and silica, wherein the filler composition is substantially devoid of alumina or silicon carbide, and the filler composition has a weight ratio of carbon to silica of at least greater than 1.0.

10. The semiconductor package according to claim 9, wherein the base material includes an epoxy component.

11. The semiconductor package according to claim 9, further comprising a silane coupling agent.

12. The semiconductor package according to claim 11, wherein the silane coupling agent is selected from 3-aminopropyltriethoxysilane and 3-glycidoxypropyltriethoxysilane.

13. A semiconductor package, comprising:
a molding compound comprising:
a base material; and
a filler composition, wherein the filler composition comprises particles each including both carbon and silica, wherein the filler composition is substantially devoid of alumina or silicon carbide, and the filler composition has a weight ratio of carbon to silica of at least greater than 1.0.

14. The semiconductor package according to claim 13, further comprising a silane coupling agent.

15. A semiconductor package, comprising:
an adhesive comprising:
a base material; and
a filler composition, wherein the filler composition comprises particles each including both carbon and silica, wherein the filler composition is substantially devoid of alumina or silicon carbide, and the filler composition has a weight ratio of carbon to silica of at least greater than 1.0.

16. The semiconductor package according to claim 15, further comprising a silane coupling agent.

17. A process for preparing a semiconductor package that comprises a filler composition, comprising:
(a) combining phytoliths and a solvent to form a dispersion;
(b) modifying a pH value of the dispersion to form an acidic dispersion;
(c) carrying out a heat treatment on the acidic dispersion; and
(d) calcining at least a portion of the acidic dispersion in a reducing environment to form the filler composition.

18. The process according to claim 17, wherein the phytoliths are obtained from husks, rice straws, or mixtures thereof.

19. The process according to claim 17, wherein carrying out the heat treatment in (c) includes applying a hydrothermal process at a temperature in a range of 50° C. to 200° C.

20. The process according to claim 17, wherein calcining in (d) is carried out at a temperature in a range of 600° C. to 1000° C.

21. The process according to claim 17, wherein calcining in (d) is carried out in a nitrogen environment.

22. The process according to claim 17, further comprising applying microwave irradiation to the filler composition.
